(19) United States
(12) Patent Application Publication
(10) Pub. No.: US 2009/0280599 A1
(43) Pub. Date: Nov. 12, 2009

(54) PHASE CHANGE MEMORY DEVICE AND METHOD OF FABRICATION

(75) Inventors: Dong-Hyun Im, Seoul (KR); Do-Hyung Kim, Seongnam-si (KR); Hye-Young Park, Seongnam-si (KR); Sung-Lae Cho, Yongin-si (KR); Jin-Il Lee, Seongnam-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: Samsung Electronics Co., Ltd., Suwon-si (KR)

(21) Appl. No.: 12/434,721

(22) Filed: May 4, 2009

(30) Foreign Application Priority Data
May 7, 2008 (KR) 10-2008-0042484

(51) Int. Cl. H01L 21/00

(52) U.S. Cl. 438/102; 257/E21.001

(57) ABSTRACT

A phase change memory device includes a bottom electrode on a substrate, a phase change material pattern on the bottom electrode, and a top electrode on the phase change material pattern. The phase change material pattern includes at least 50 percent antimony (Sb).

### PRIORITY STATEMENT

This U.S. non-provisional patent application claims priority under 35 U.S.C § 119 to Korean Patent Application 10-2008-0042484 filed on May 7, 2008, the subject matter of which is hereby incorporated by reference.

### BACKGROUND

The present invention relates to semiconductor memory devices, and more specifically to phase change memory devices and corresponding methods of fabrication.

Semiconductor memory devices may be generally classified as volatile or non-volatile in their operating nature. Volatile memory devices lose stored data when applied power is interrupted, while non-volatile memory devices retain stored data in the absence of applied power. Flash memory is currently a very popular form of non-volatile memory, but phase change memory devices are increasingly attractive as an alternative form of non-volatile memory.

A phase change memory device includes a phase change material operated as a data storage element. The phase change material typically exhibits one of two stable states induced by the controlled application of heat. If a phase change material is cooled after being heated to a temperature higher than its melting temperature, it assumes an amorphous state. However, if the phase change material is cooled after being heated at a temperature lower than its melting temperature but higher than its crystallization temperature, it assumes a crystalline state.

A resistivity of a phase change material having an amorphous state is typically higher than that of a phase change material having a crystalline state. Thus, current flowing through the phase change material may be sensed to determine whether data stored in a phase change memory cell corresponds to a logical value of “1” or “0”. In addition to non-volatile operation, phase change memory devices enjoy advantages such as a high-speed read/write operations and a low operating voltage. Nonetheless, integration density for phase change memory devices remains lower than that of flash memory.

### SUMMARY

Embodiments of the present invention provide a phase change memory device. In one embodiment, a phase change memory device is provided that comprises; a bottom electrode formed in a lower region of a contact hole disposed in an insulating layer on a substrate, a phase change material pattern formed in an upper region of the contact hole in electrical contact with the bottom electrode, and a top electrode formed on the insulating layer and in electrical contact with the phase change material pattern, wherein the phase change material pattern is formed from a material including at least 50 percent antimony (Sb).

In another embodiment, a method of forming a phase change memory device is provided and comprises; forming a bottom electrode on a substrate, forming a phase change material pattern on the bottom electrode, and forming a top electrode on the phase change material pattern, wherein the phase change material pattern includes antimony (Sb), and the content of the Sb in the phase change material pattern is at least 50 percent.

### BRIEF DESCRIPTION OF THE DRAWINGS

FIGS. 1A through 1D are related cross-sectional views illustrating a phase change memory device according to an embodiment of the invention and a method of fabricating same.

FIGS. 2A through 2C are related cross-sectional views illustrating a phase change memory device according to another embodiment of the invention and a method of fabricating same.

FIGS. 3A through 3C are related cross-sectional views illustrating a phase change memory device according to another embodiment of the invention and a method of fabricating same.

FIGS. 4A through 4E are related cross-sectional views illustrating a phase change memory device according to another embodiment of the invention and a method of fabricating same.

FIGS. 5A through 5E are related cross-sectional views illustrating a phase change memory device according to another embodiment of the invention and a method of fabricating same.

FIGS. 6A and 6B shows current-resistance characteristics of a phase change material pattern according to embodiments of the invention.

FIG. 7A is a graph illustrating a relationship between supply time of an antimony precursor and temperature of a reactor and the content of antimony in a phase change material pattern.

FIG. 7B is a graph illustrating crystallinity of the phase change material pattern according to the supply time of the antimony precursor.

FIG. 8 is a schematic diagram of a system including a phase change memory device according to embodiments of the invention.

### DESCRIPTION OF EMBODIMENTS

Embodiments of the invention will now be described in some additional detail with reference to the accompanying drawings. The invention may, however, be embodied in many different forms and should not be construed as being limited to only the illustrated embodiments. Rather, these embodiments are presented as teaching examples.

In the drawings, the thicknesses of layers and regions may be exaggerated for clarity. It will also be understood that when a layer is referred to as being “on” another layer or substrate, it may be directly on the other layer or substrate, or intervening layers may also be present. Throughout the written description and drawings, like numbers are used to refer to like or similar elements.

A phase change memory device according to an embodiment of the invention and a method of fabricating same will now be described with reference to Figures (FIGS.) 1A through 1D.

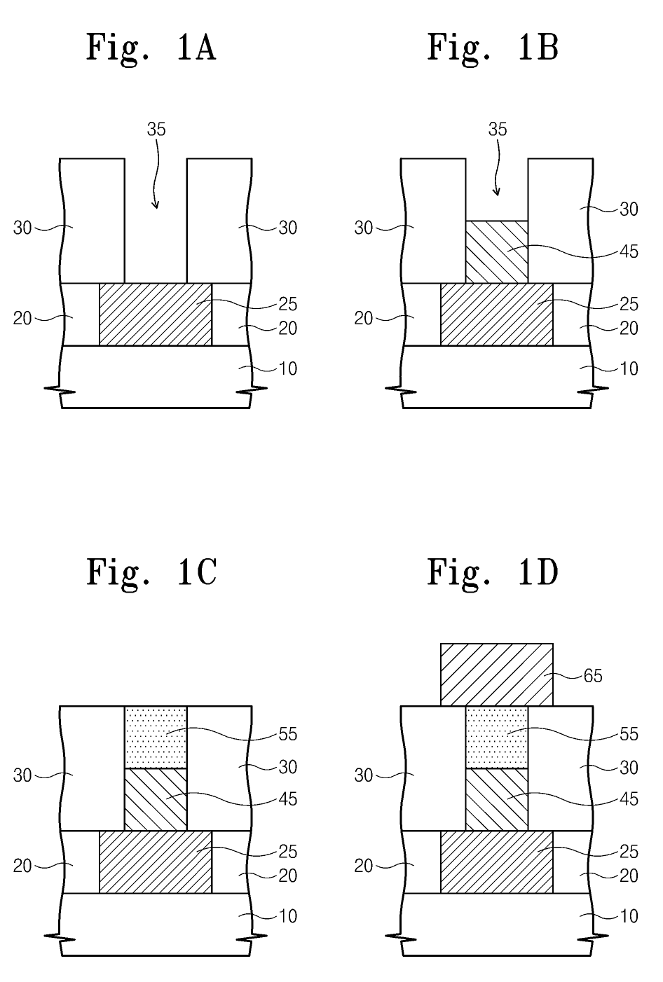

Referring to FIG. 1A, a first insulating layer 20 including a conductive pattern 25 is formed on a substrate 10 which may be a semiconductor substrate such as, for example, a single-crystalline silicon substrate or an SOI substrate. The substrate 10 may include a diode or a transistor which is electrically connected to a conductive pattern 25. The substrate 10 may further include a conductive line (e.g., a wordline) which is electrically connected to the diode. The conductive pattern 25 may include a material having super heat transfer efficiency and reduced operating current within the phase change memory device. For example, the conductive pattern 25 may be formed from at least one material selected from a group of materials consisting of: metals (or metal alloys) such as titanium, hafnium, zirconium, vanadium, niobium, tantalum, tungsten, aluminum, copper, tungsten titanium, and molybdenum; binary metal nitrides such as titanium nitride, hafnium nitride, zirconium nitride, vanadium nitride, niobium nitride, tantalum nitride, tungsten nitride, and molybdenum nitride; metal oxides such as iridium oxide and ruthenium oxide; ternary metal nitrides such as titanium carbonitride, tantalum carbonitride, silicon titanium nitride, silicon tantalum nitride, aluminum titanium nitride, aluminum tantalum nitride, boron titanium nitride, silicon zirconium nitride, silicon tungsten nitride, boron tungsten nitride, aluminum zirconium nitride, silicon molybdenum nitride, aluminum molybdenum nitride, tantalum oxynitride, titanium oxynitride, tungsten oxynitride, and tantalum oxynitride; silicon; and combinations thereof.

In the illustrated embodiment of FIGS. 1A through 1D, the conductive pattern 25 is assumed to be formed from tungsten.

A second insulating layer 30 including a contact hole 35 exposing the conductive pattern 25 is formed on the first insulating layer 20. The first and second insulating layers 20 and 30 may be formed from at least one insulating material selected from a group of insulating materials consisting of silicon oxide, silicon nitride, silicon oxynitride, and combinations thereof. The first and second insulating layers 20 and 30 may be formed using one or more conventionally understood, chemical vapor deposition (CVD) processes.

Referring to FIG. 1B, a bottom electrode 45 is formed at a lower region of the contact hole 35 on (and in electrical contact with) the conductive pattern 25. The bottom electrode 45 may be formed, for example, using an anisotropic etching process following the formation of conductive fill layer within the contact hole 35.

The bottom electrode 45 may be formed from at least one material selected from a group of materials consisting of: metals (or metal alloys) such as titanium, hafnium, zirconium, vanadium, niobium, tantalum, tungsten, aluminum, copper, tungsten titanium, and molybdenum; binary metal nitrides such as titanium nitride, hafnium nitride, zirconium nitride, vanadium nitride, niobium nitride, tantalum nitride, tungsten nitride, and molybdenum nitride; metal oxides such as iridium oxide and ruthenium oxide; ternary metal nitrides such as titanium carbonitride, tantalum carbonitride, silicon titanium nitride, silicon tantalum nitride, aluminum titanium nitride, aluminum tantalum nitride, boron titanium nitride, silicon zirconium nitride, silicon tungsten nitride, boron tungsten nitride, aluminum zirconium nitride, silicon molybdenum nitride, aluminum molybdenum nitride, tantalum oxynitride, titanium oxynitride, tungsten oxynitride, and tantalum oxynitride; silicon; and combinations thereof.

In the embodiment illustrated in FIGS. 1A through 1D, the bottom electrode 45 is assumed to be formed from titanium nitride.

Referring to FIG. 1C, a phase change material pattern 55 is formed in an upper region of the contact hole 35 on (and in electrical contact with) the bottom electrode 45. The phase change material pattern 55 may be formed, for example, using a planarization process to expose the second insulating layer 30 after forming a phase change material layer to fill the contact hole 35 on the bottom electrode 45. The phase change material pattern 55 in the illustrated example thus exhibits a plug shape. The planarization process may include one or more conventionally under stood chemical mechanical polishing (CMP) process(es) and/or etch-back process(es).

In the embodiment illustrated in FIGS. 1A through 1D, the phase change material pattern 55 is assumed to include antimony (Sb). In one embodiment, the content of the antimony (Sb) within the phase change material may be 50 percent or more. For example, the phase change material pattern 55 may be formed from a chalcogenide including Sb. In one embodiment, the phase change material pattern 55 includes antimony-tellurium (Sb—Te), and the Sb—Te may be doped with one or more selected impurities, such as germanium (Ge), sulfur (S), selenium (Se), lead (Pb), nitrogen (N), carbon (C), and/or oxygen (O).

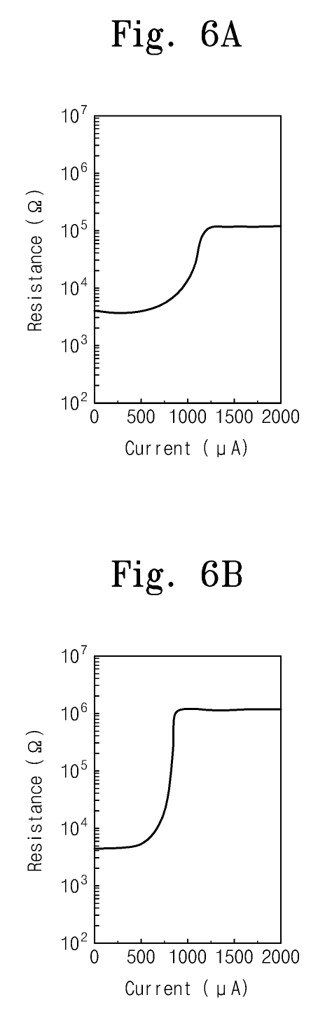

FIGS. 6A and 6B show exemplary current-resistance characteristics for a phase change material pattern according to certain embodiments of the invention. FIG. 6A shows current-resistance characteristics in an example where a phase change material pattern is formed of antimony-tellurium (Sb—Te) (hereinafter, “example 1”), and FIG. 6B shows current-resistance characteristics in another example where the phase change material pattern is formed of antimony-tellurium (Sb—Te) doped with germanium (Ge) (hereinafter, “example 2”). The phase change material pattern is formed to have an amorphous state where the content of Sb is 50 percent or more. Referring to FIGS. 6A and 6B, both examples 1 and 2 exhibit current-resistance characteristics where the phase change material pattern may act as a memory. It is noted that reset resistance in the example 2 is higher than that of example 1.

The phase change material pattern 55 may be formed to have an amorphous state by means of conventionally understood chemical vapor deposition (CVD) process(es) and/or atomic layer deposition (ALD) process(es). For example, the phase change material pattern 55 may be formed of antimony-tellurium (Sb—Te) by supplying a Sb-containing source (hereinafter referred to as “Sb precursor”) and Te-containing source (hereinafter referred to as “Te precursor”) into a reactor where the deposition process is performed. Thereafter, the Sb—Te may be doped with an impurity such as germanium (Ge), sulfur (S), selenium (Se), lead (Pb), nitrogen (N), carbon (C), and oxygen (O). If the content of the impurity in the phase change material pattern 55 is 10 percent or more, the phase change material pattern 55 may have a crystalline state, not an amorphous state. Thus, the content of the impurity in the phase change material pattern 55 should be 10 percent or less. The Sb precursor and the Te precursor may be supplied with inert gas such as argon (Ar), helium (He), and neon (Ne). When the Sb precursor and the Te precursor are supplied into the reactor, reactant gas such as H₂, NH₃, N₂H₄, SiH₄, B₂H₆, O₂, O₃, and H₂O may be supplied thereinto simultaneously or separately. The reactant gas activates the Sb deposition to readily form an amorphous phase change material layer including Sb whose content is 50 percent or more. In an exemplary embodiment, NH₃ may be used as the reactant gas.

If the content of Sb in the phase change material pattern 55 is 50 percent or more, the phase change material pattern 55 may be formed to have an amorphous state and conformally formed in a contact hole 35 without voids. For example, although the contact hole 35 has a width of 100 nanometers or less, even less than 10 nanometers, the phase change material pattern 55 may be conformally formed. During the deposition process, the Sb precursor is supplied for 15 seconds or more to form an amorphous change material pattern 55 including Sb whose content is 50 percent is more. Moreover, it is necessary to maintain a temperature of the reactor at a predetermined temperature or less during the deposition process. For example, in case of a hot-wall reactor that is a batch-type reactor, a temperature of the reactor is maintained at a temperature of 275 degrees centigrade or less. And in case of a cold-wall reactor, a temperature of the reactor is maintained at a temperature of 350 degrees centigrade or less.

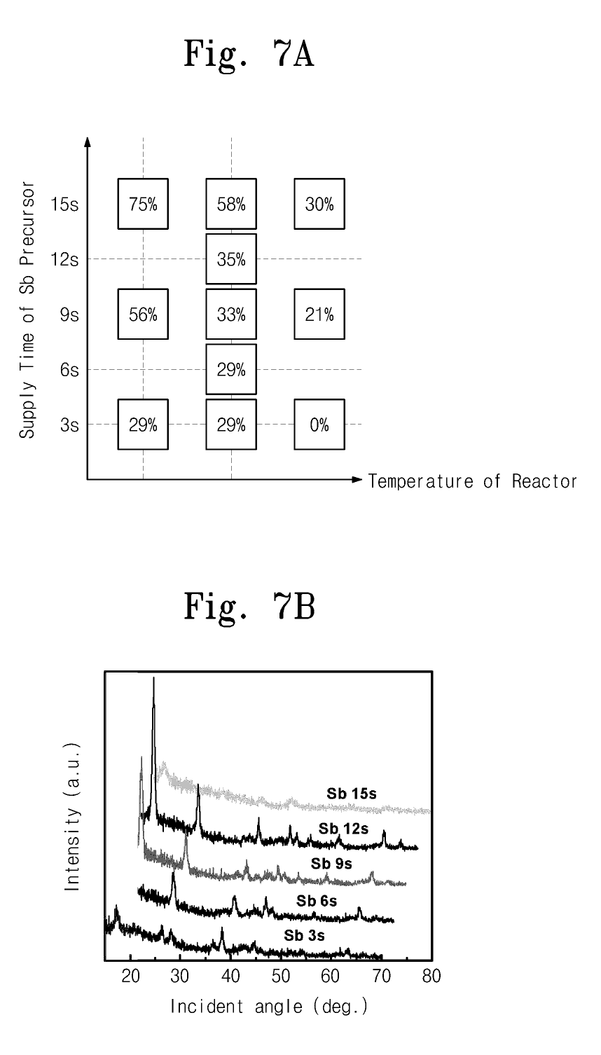

FIG. 7A shows a relationship between the content of antimony (Sb) in a phase change material pattern and supply time of an Sb precursor supplied into a hot-wall reactor and a temperature of the hot-wall reactor when the phase change material pattern is formed at the hot-wall reactor according to an embodiment of the invention. X-axis of FIG. 7A denotes a temperature of a hot-wall reactor, and Y-axis thereof denotes one-time supply time of an Sb precursor supplied to the hot-wall reactor. Undoubtedly, the Sb precursor may be supplied to the hot-wall reactor twice or more. Values in squares represent the contents of Sb in a phase change material pattern, respectively.

Referring to FIG. 7A, it can be seen that the more supply time of an Sb precursor and the lower a temperature of a hot-wall reactor, the greater the content of Sb in a phase change material pattern. For example, when a temperature of a hot-wall reactor is 225 degrees centigrade and one-time supply time of an Sb precursor is 15 seconds, the content of Sb in a phase change material pattern may be 58 percent. And when a temperature of a hot-wall reactor is 200 degrees centigrade and one-time supply time of an Sb precursor is 15 seconds, the content of Sb in a phase change material pattern may be 75 percent. And when a temperature of a hot-wall reactor is 225 degrees centigrade and one-time supply time of an Sb precursor is 9 seconds, the content of Sb in a phase change material pattern may be 56 percent. That is, the content of Sb in a phase change material pattern may be controlled to be at least 50 percent by adjusting supply time of an Sb precursor and a temperature of a reactor.

FIG. 7B shows a crystallinity of a phase change material pattern according to supply time of an Sb precursor. Specifically, a graph of FIG. 7B shows the intensity (Y-axis) sensed according to incident angles (X-axis) by irradiating X-tray to a phase change material pattern. The phase change material pattern is classified based on supply time of an Sb precursor supplied when the phase change material pattern is formed.

Referring to FIG. 7B, when one-time supply time of the Sb precursor is 12 seconds or less, a phase change material pattern may include a crystalline portion. However, when the one-time supply time of the Sb precursor is 15 seconds or more, the phase change material pattern may have an amorphous state.

Referring now to FIG. 1D, a top electrode 65 is formed on a phase change material pattern 55. The top electrode 65 may be formed by fabricating a conductive layer on a second insulating layer 30 including the phase change material pattern 55 and thereafter patterning the conductive layer.

The top electrode 65 may be formed from at least one material selected from a group of materials consisting of: metals (or metal alloys) such as titanium, hafnium, zirconium, vanadium, niobium, tantalum, tungsten, aluminum, copper, tungsten titanium, and molybdenum; binary metal nitrides such as titanium nitride, hafnium nitride, zirconium nitride, vanadium nitride, niobium nitride, tantalum nitride, tungsten nitride, and molybdenum nitride; metal oxides such as iridium oxide and ruthenium oxide; ternary metal nitrides such as titanium carbonitride, tantalum carbonitride, silicon titanium nitride, silicon tantalum nitride, aluminum titanium nitride, aluminum tantalum nitride, boron titanium nitride, silicon zirconium nitride, silicon tungsten nitride, boron tungsten nitride, aluminum zirconium nitride, silicon molybdenum nitride, aluminum molybdenum nitride, tantalum oxynitride, titanium oxynitride, tungsten oxynitride, and tantalum oxynitride; silicon; and combinations thereof.

In the embodiment illustrated in FIGS. 1A through 1D, the conductive layer 80 is assumed to be formed from a stacked combination of titanium and titanium nitride.

Phase change memory devices according to other embodiments of the present invention will now be described in some additional detail with reference to accompanying drawings. Without specific mention of a substrate, a conductive pattern, bottom and top electrodes, first and second insulating layers, a phase change material layer, and a phase change material pattern that are components of the respective phase change memory device, their description in the foregoing embodiment may be applied to these embodiments.

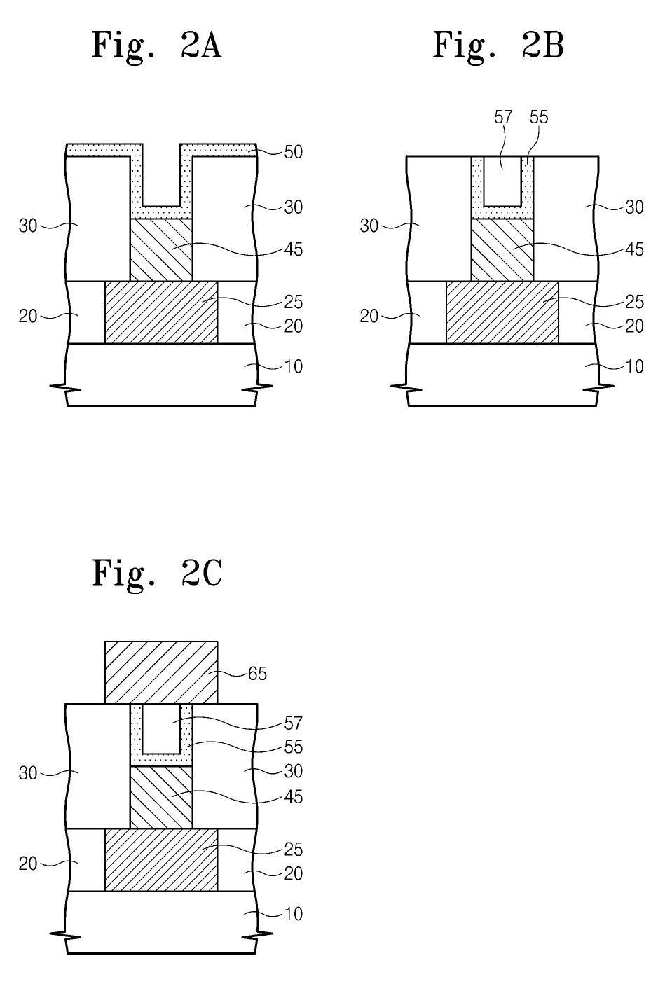

A phase change memory device according to another embodiment of the invention will now be described with reference to FIG. 2A through 2C.

Referring to FIG. 2A, a phase change material layer 50 is formed on the resultant structure of FIG. 1B. The phase change material layer 50 may be conformally formed on a top surface of a bottom electrode 45 and on sidewalls of the upper region of the contact hole 35 formed in the second insulating layer 30.

Referring to FIG. 2B, a phase change material pattern 55 and an insulating pattern 57 are formed in the contact hole 35 on the bottom electrode 45. The phase change material pattern 55 and the insulating pattern 57 may be formed by forming an insulating layer on the phase change material layer 50 and performing a planarization process to expose the second insulating layer 30. One or more conventionally understood planarization process(es) including, for example, one or more chemical mechanical polishing (CMP) process(es) and/or etch-back process(es) may be used. In the illustrated embodiment of FIGS. 2A through 2C, the phase change material pattern 55 exhibits a cup shape. In one embodiment, the thickness of the phase change material pattern 55 will be 10 nanometers or less.

The insulating pattern 57 may be formed from at least one insulating materials selected from a group of insulating materials including; silicon oxide, silicon nitride, silicon oxynitride, and/or combinations thereof.

Referring to FIG. 2C, the top electrode 65 is then formed on the phase change material pattern 55. As before, the top electrode 65 may be formed by patterning a conductive layer disposed on the second insulating layer 30, change material pattern 55, and the insulating pattern 57.

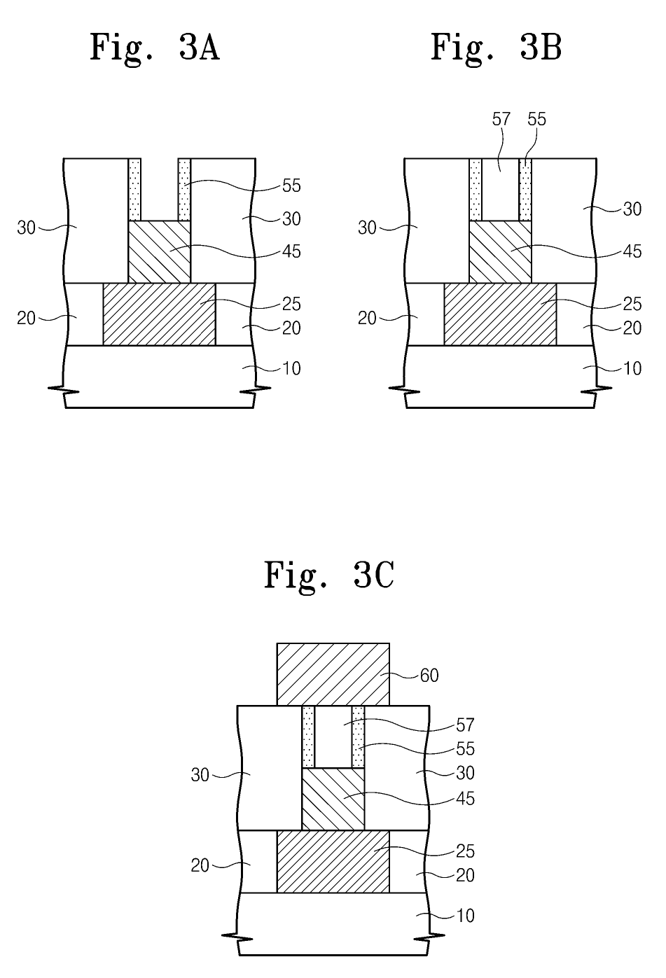

A phase change memory device according to another embodiment of the invention and a method of fabricating same will now be described with reference to FIGS. 3A through 3C.

Referring to FIG. 3A, a phase change material pattern 55 is formed on sidewalls of the upper region of contact hole 35 in electrically contact with the bottom electrode 45. The phase change material pattern 55 of this particular embodiment may be formed, for example, by anisotropically etching the resultant structure shown in FIG. 2A. Thus, the phase change material pattern 55 illustrated in FIGS. 3A through 3C will exhibit a ring shape within the upper region of the contact hole 35 and exposing the top surface of the bottom electrode 45.

Referring to FIG. 3B, an insulating pattern 57 is then formed in the upper region of the contact hole 35 on the bottom electrode 45 and within the ring shaped phase change material pattern 55. The insulating pattern 57 may be formed by performing a planarization process to expose the second insulating layer 30 and the phase change material pattern 55 after forming an insulating layer to fill the contact hole 35 on the bottom electrode 45. The planarization process may include a chemical mechanical polishing (CMP) process or an etch-back process. The insulating pattern 57 may be formed of, for example, silicon oxide, silicon nitride, silicon oxynitride or combination thereof.

In the particular embodiment illustrated in FIGS. 3A through 3C, the insulating pattern 57 may be formed from a material having an etch selectivity with respect to the phase change material pattern 55 and the second insulating layer 30.

Referring to FIG. 3C, a top electrode 65 is formed on the phase change material pattern 55. The top electrode 65 may be formed by forming a conductive layer on the second insulating layer 30 including the phase change material pattern 55 and the insulating pattern 57 and patterning the conductive layer.

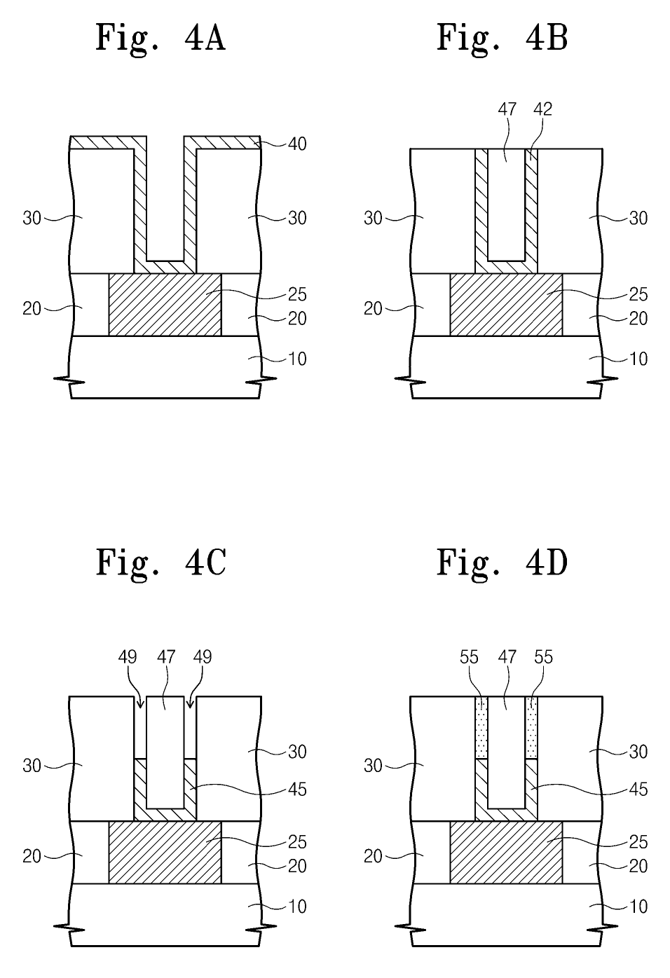

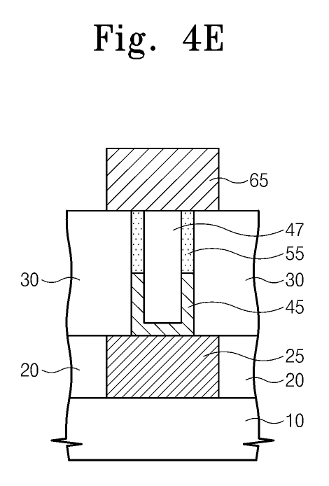

A phase change memory device according to still another embodiment of the invention and a method of fabricating same will now be described with reference to FIGS. 4A through 4E.

Referring to FIG. 4A, a conductive layer 40 is formed on the resultant structure of FIG. 1A. The conductive layer 40 is conformally formed on the top surface of the conductive pattern 25, the exposed sidewalls of contact hole 35 disposed through the second insulating layer 30.

Referring to FIG. 4B, a conductive pattern 42 and an insulating pattern 47 are formed in the contact hole 35 on the conductive pattern 25. The conductive pattern 42 and the insulating pattern 47 may be formed by performing a planarization process to expose the second insulating layer 30 after forming an insulating layer on the conductive layer 40 to fill the contact hole 35. The insulating pattern 47 may be formed of, for example, silicon oxide, silicon nitride, silicon oxynitride or combination thereof.

Referring to FIG. 4C, an upper portion of the conductive pattern 42 is recessed to form a cup shaped bottom electrode 45. A gap region 49 is thus formed between upper portions of sidewalls of the second insulating layer 30 and opposing sidewall portions of the insulating pattern 47. The width of the gap region 49 in certain embodiments will be 10 nanometers or less.

Referring to FIG. 4D, a phase change material pattern 55 is formed to fill the gap region 49 in electrical contact with the bottom electrode 45. The phase change material pattern 55 may be formed by performing a planarization process to expose the second insulating layer 30 and the insulating pattern 47 after forming a phase change material layer to fill the gap region 49. The planarization process may include, for example, a chemical mechanical polishing (CMP) process or an etch-back process.

Referring to FIG. 4E, a top electrode 65 is formed on the phase change material pattern 55. The top electrode 65 may be formed by forming a conductive layer on the second insulating layer 30 on the phase change material pattern 55 and the insulating pattern 47 and performing the conductive layer.

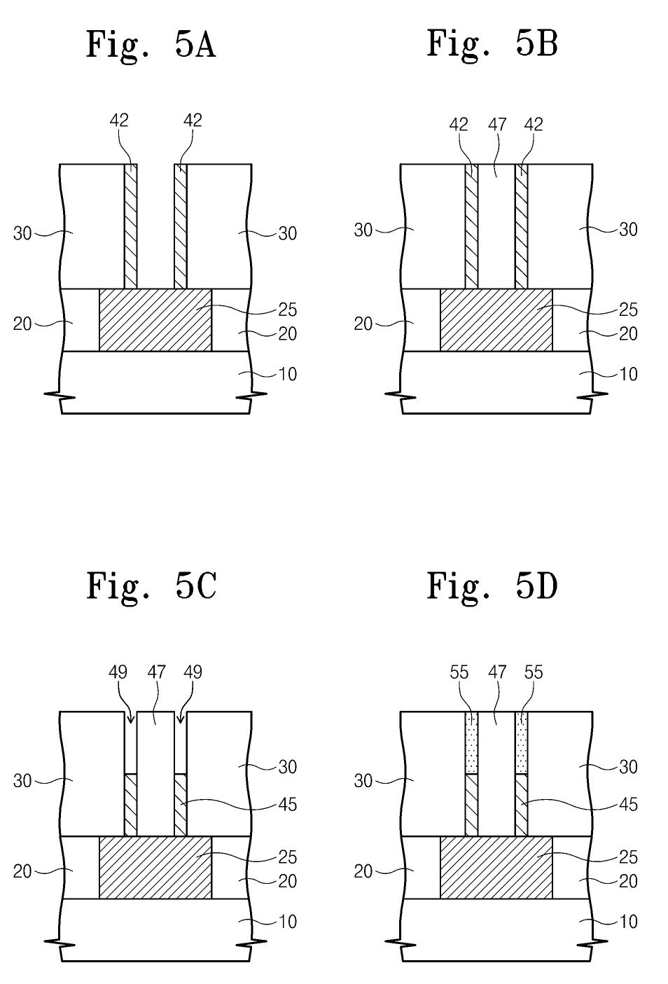

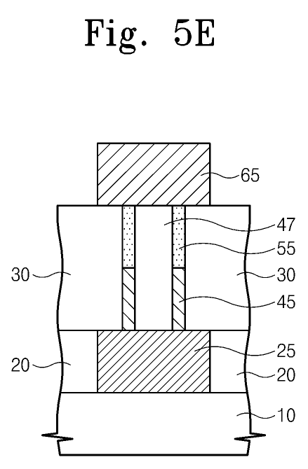

A phase change memory device according to yet another embodiment of the invention and a method of fabricating same will be described below with reference to FIGS. 5A through 5E.

Referring to FIG. 5A, a conductive pattern 42 is formed on exposed sidewalls of contact hole 35 disposed through the second insulating layer 30. The resulting ring shaped conductive pattern 42 may be formed by anisotropically etching the resultant structure of FIG. 4A, and a portion of the top surface of the conductive pattern 25 will be exposed by the ring shaped conductive pattern 42.

Referring to FIG. 5B, an insulating pattern 47 is formed on the conductive pattern 25 to fill the contact hole 35. The insulating pattern 47 may be formed by performing a planarization process to expose the second insulating layer 30 after forming an insulating layer to fill the contact hole 35. The planarization process may include, for example, a chemical mechanical polishing (CMP) process or an etch-back process. The insulating pattern 47 may be formed of silicon oxide, silicon nitride, silicon oxynitride or combination thereof.

In this particular embodiment, the insulating pattern 47 may be formed from a material having an etch selectivity with respect to the conductive pattern 42 and the second insulating layer 30.

Referring to FIG. 5C, the conductive pattern 42 is recessed to form a ring shaped bottom electrode 45. A gap region 49 is formed between the second insulating layer 30 and the insulating pattern 47. The width of the gap region 49 in certain embodiment will be 10 nanometers or less.

Referring to FIG. 5D, a phase change material pattern 55 is formed in the gap region 49 on the bottom electrode 45. The phase change material pattern 55 may be formed by performing a planarization process to expose the second insulating layer 30 and the insulating pattern 47 after forming a phase change material layer to fill the gap region 49. The planarization process may include, for example, a chemical mechanical polishing (CMP) process or an etch-back process.

Referring to FIG. 5E, a top electrode 65 is formed on the phase change material pattern 55. The top electrode 65 may be formed by forming a conductive layer on the second insulating layer 30 including the phase change material pattern 55 and the insulating pattern 47 and pattering the conductive layer.

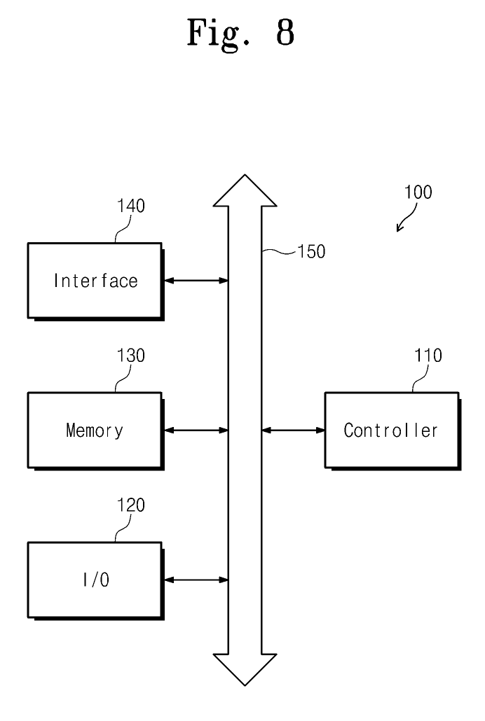

FIG. 8 is a schematic diagram of a system 100 including a phase change memory device according to an embodiment of the invention. The system 100 may be used in wireless communication devices such as, for example, personal digital assistants (PDAs), laptop computers, portable computers, web tablets, wireless telephones, mobile phones, digital music players, and all devices receiving and transmitting information in a wireless environment.

The system 100 may include a controller 110, an input/output device (I/O) 120 such as a keypad, a keyboard, and a display, a memory 130, and a wireless interface 140, which are connected through a bus 150. The controller 110 may include, for example, at least one microprocessor, a digital signal processor, a microcontroller, and/or similar devices. The memory 130 may be used, for example, to store commands executed by the controller 110. In addition, the memory 130 may be used to store user data. The memory 130 includes a phase change memory according to the exemplary embodiments of the present invention. The memory 110 may further include another type of memory, a random-access volatile memory, and various other types of memories.

The system 100 may use wireless interface 140 to transmit/receive data to/from a wireless communication network using an RF signal. The wireless interface 140 may include, for example, an antenna, a wireless transceiver, etc.

The system 100 according to embodiments of the present invention may be used in communication interface protocols of a third generation wireless communication system such as CDMA, GSM, NADC, E-TDMA, WCDAM, CDMA2000, etc.

According to certain embodiments of the invention, a phase change material pattern can be conformally formed in a contact hole having a small width, e.g., 100 nanometers or less to achieve high integration of a phase change memory device. Further, a phase change material pattern can be formed in a contact hole without voids to enhance relativity of a phase change memory device.

Although the present invention has been described in connection with selected embodiments of the invention illustrated in the accompanying drawings, it is not limited thereto. It will be apparent to those skilled in the art that various substitutions, modifications and changes may be made without departing from the scope of the invention as defined by the attached claims and their equivalent.

1-12. (canceled)

13. A method of forming a phase change memory device, comprising:
forming a bottom electrode on a substrate;
forming a phase change material pattern on the bottom electrode; and
forming a top electrode on the phase change material pattern,
wherein the phase change material pattern includes antimony (Sb), and the content of the Sb in the phase change material pattern is at least 50 percent.

14. The method of claim 13, wherein forming the phase change material pattern comprises:
providing the substrate to a reactor;
supplying an antimony (Sb) precursor, a tellurium (Te) precursor, and a reactant gas to the reactor simultaneously or sequentially; and
performing a chemical vapor deposition (CVD) or atomic layer deposition (ALD) process on the substrate.

15. The method of claim 13, wherein the phase change material pattern is formed in an amorphous state.

16. The method of claim 13, wherein the reactant gas includes ammonia (NH₃).

17. The method of claim 13, wherein the content of the Sb in the phase change material pattern is controlled by a temperature of the reactor and supply time of the Sb precursor supplied to the reactor.

18. The method of claim 17, wherein the reactor includes a hot-wall reactor or a cold-wall reactor, the hot-wall reactor being maintained at a temperature of 275 degrees centigrade or less and the cold-wall reactor being maintained at a temperature of 350 degrees centigrade or less.

19. The method of claim 13, wherein forming the phase change material pattern comprises:
forming an insulating layer with a contact hole on the substrate, the contact hole being formed to expose the bottom electrode,
wherein the phase change material pattern is formed within the contact hole.

20. The method of claim 19, wherein a width of the contact hole is 100 nanometers or less.
